(19) United States
(12) Patent Application Publication
(10) Pub. No.: US 2025/0132280 A1
(43) Pub. Date: Apr. 24, 2025

(54) CHIP ATTACH FILM, SEMICONDUCTOR PACKAGE INCLUDING THE SAME, AND METHOD OF MANUFACTURING SEMICONDUCTOR PACKAGE

(71) Applicant: Samsung Electronics Co., Ltd., Suwon-si (KR)

(72) Inventors: Hansol Yoo, Suwon-si (KR); Myoungchul Eum, Suwon-si (KR)

(21) Appl. No.: 18/895,900

(22) Filed: Sep. 25, 2024

(30) Foreign Application Priority Data
Oct. 24, 2023 (KR) 10-2023-0143250

(51) Int. Cl. H01L 23/00; H01L 21/56; H01L 25/18; H10B 80/00

(52) U.S. Cl. CPC H01L 24/29; H01L 21/565; H01L 24/32; H01L 24/48; H01L 24/73; H01L 24/13; H01L 24/16; H01L 25/18; H01L 2224/13111; H01L 2224/13118; H01L 2224/13139; H01L 2224/16225; H01L 2224/29005; H01L 2224/2929; H01L 2224/2939; H01L 2224/29499; H01L 2224/32145; H01L 2224/32225; H01L 2224/48147; H01L 2224/48227; H01L 2224/73204; H01L 2224/73265; H01L 2225/06506; H01L 2225/0651; H01L 2225/06517; H01L 2225/06562; H01L 2924/1431; H10B 80/00

(57) ABSTRACT

A chip attach film includes an adhesive layer, and a filler dispersed in the adhesive layer and including an organic material, wherein a thickness of the adhesive layer is about 0.5 μm to about 3 μm, and wherein an average particle diameter of the filler is equal to or greater than about 0.8 times the thickness of the adhesive layer, and less than about 1 times the thickness of the adhesive layer.

### CROSS-REFERENCE TO RELATED APPLICATION

This application is based on and claims ranking under 35 U.S.C. § 119 to Korean Patent Application No. 10-2023-0143250, filed Oct. 24, 2023, in the Korean Intellectual Property office, the disclosure of which is incorporated by reference herein in their entirety.

### BACKGROUND

The inventive concept relates to a chip attach film, a semiconductor package including the chip attach film, and a method of fabricating the semiconductor package. More particularly, the inventive concept relates to the chip attach film including an organic filler, a semiconductor package including the chip attach film, and a method of manufacturing the semiconductor package.

Electronic devices have become more compact and lighter according to development of the electronics industry and demands of users. Accordingly, large capacity and high integration may be required for semiconductor packages used in electronic devices. According to the requirements, semiconductor packages may be implemented in a stacked structure of the semiconductor packages. In such a semiconductor package structure, a semiconductor chip may be bonded and fixed on a package substrate or another semiconductor chip by using a chip attach film. Recently, for convenience in performing the process, a semiconductor package is fabricated by attaching a chip attach film to the back of a wafer before the wafer sawing process, and stacking semiconductor chips with the chip attach film attached to the semiconductor chips on a package substrate or other semiconductor chips after the wafer sawing.

### SUMMARY

Embodiments of the inventive concept may provide a chip attach film, which is relatively thin and has an improved thickness uniformity.

Embodiments of the inventive concept may provide a semiconductor package having a reduced size and improved structural reliability.

According to an aspect of the inventive concept, there is provided a chip attach film including an adhesive layer, and a filler dispersed in the adhesive layer and including an organic material, wherein a thickness of the adhesive layer is about 0.5 μm to about 3 μm, and wherein an average particle diameter of the filler is equal to or greater than about 0.8 times the thickness of the adhesive layer, and less than about 1 times the thickness of the adhesive layer.

According to another aspect of the inventive concept, there is provided a semiconductor package including a substrate, a first semiconductor chip on the substrate, a chip stack which is on the substrate and includes a plurality of second semiconductor chips stacked in a second direction, and is spaced apart from the first semiconductor chip in a first direction, and a bonding wire connected to the chip stack and the substrate, wherein the chip stack further includes a chip attach film between the stacked plurality of second semiconductor chips, and wherein the chip attach film includes an adhesive layer, and a filler dispersed in the adhesive layer and including an organic material, a thickness of the chip attach film is about 0.5 μm to about 3 μm, and an average particle diameter of the filler is equal to or greater than about 0.8 times the thickness of the chip attach film and less than about 1 times the thickness of the chip attach film.

According to another aspect of the inventive concept, there is provided a method of manufacturing a semiconductor package including mounting a first semiconductor chip on a substrate, forming a chip stack spaced apart in a first direction from the first semiconductor chip on the substrate, forming a bonding wire connected to the chip stack and the substrate, and forming a molding layer on the first semiconductor chip, the chip stack, and the bonding wire, wherein the forming of the chip stack includes stacking a plurality of second semiconductor chips in a second direction including a chip attach film formed on an one surface of the plurality of second semiconductor chips, and wherein the chip attach film includes an adhesive layer, and a filler dispersed in the adhesive layer and including an organic material, a thickness of the chip attach film is about 0.5 μm to about 3 μm, and an average particle diameter of the filler is equal to or greater than about 0.8 times the thickness of the chip attach film and less than about 1 times the thickness of the chip attach film.

### BRIEF DESCRIPTION OF THE DRAWINGS

Embodiments will be more clearly understood from the following detailed description taken in conjunction with the accompanying drawings in which:

FIG. 1 is a cross-sectional view of a chip attach film according to an embodiment;

FIG. 2 is a conceptual view of materials included in a chip attach film according to an embodiment;

FIG. 3 is a cross-sectional view of a semiconductor package according to an embodiment;

FIG. 4 is an enlarged view of region EX1 in FIG. 3; and

FIGS. 5, 6A, 6B, 7A, 7B, 8, and 9 are cross-sectional views that illustrate a method of manufacturing a semiconductor package according to embodiments.

### DETAILED DESCRIPTION OF THE EMBODIMENTS

Hereinafter, embodiments of the inventive concept are described in detail with reference to the accompanying drawings. Identical reference numerals are used for the same constituent elements in the drawings, and duplicate descriptions thereof are omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination. As used herein, reference may be made to a horizontal direction or first direction and a vertical direction or second direction with respect to a particular orientation or a chip attach film and/or semiconductor package illustrated in the drawings. It will be understood that the chip attach film and/or semiconductor package may be oriented in different ways or viewed from different perspectives that change the horizontal and vertical planes.

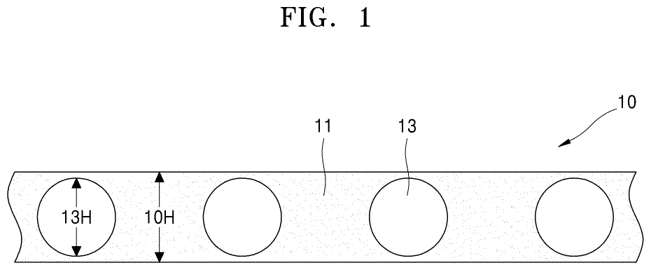

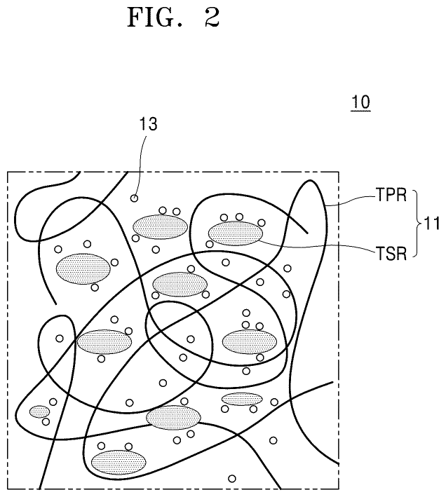

FIG. 1 is a cross-sectional view of a chip attach film 10 according to an embodiment. FIG. 2 is a conceptual view of materials included in the chip attach film 10 according to an embodiment.

Referring to FIGS. 1 and 2, the chip attach film 10 may include an adhesive layer 11 and a filler 13. The chip attach film 10 may be used as a film for bonding stacked semiconductor chips to each other when the semiconductor package is fabricated.

In the embodiment, a thickness 10H of the chip attach film 10 may be about 0.5 μm to about 3 μm. For example, the thickness 10H of the chip attach film 10 may be about 1 μm. In this example, the thickness 10H of the chip attach film 10 may mean a vertical or second direction length of the chip attach film 10. When the thickness 10H of the chip attach film 10 is too large, it may be difficult to fabricate an electronic device with a relatively thin profile, to which the chip attach film 10 is applied.

The adhesive layer 11 may have a film shape. Because the adhesive layer 11 has a film shape, the thickness 10H of the chip attach film 10 may be substantially the same as a thickness of the adhesive layer 11.

The adhesive layer 11 may include a thermosetting polymer TSR and a binder polymer TPR. In FIG. 2, the thermosetting polymer TSR may be illustrated as an ellipse, and the binder polymer TPR may be illustrated as solid line strands. The thermosetting polymer TSR and the binder polymer TPR may be bonded to each other by using a curing process and may constitute a polymer matrix constituting the adhesive layer 11. The curing process may include, for example, a thermal process, but embodiments are not limited thereto.

In some embodiments, the thermosetting polymer TSR may be one or more selected from the group including, for example, epoxy polymers and bismaleimide polymers.

The epoxy-based polymer may include, for example, a bisphenol A-type epoxy resin, a bisphenol F-type epoxy resin, a naphthalene-type epoxy resin, an aminophenol-type epoxy resin, a water-added bisphenol-type epoxy resin, an alicyclic epoxy resin, an alcohol ether-type epoxy resin, an annular aliphatic-type epoxy resin, a fluorene-type epoxy resin, a siloxane-based epoxy resin, or the like, but embodiments are not limited thereto. These resins may be used alone or in a mixture of two or more.

The bismaleimide-based polymer may include a polymer obtained by polymerization of maleimide monomers including one or more or two or more maleimide radicals.

The maleimide monomer may include, for example, n-phenylmaleimide, n-(2-methylphenyl) maleimide, n-(4-methylphenyl) maleimide, n-(2,6-dimethylphenyl) maleimide, bis (4-maleimidophenyl) maleimide, 2,2-bis (4-(4-(4-maleimidophenoxy)-phenyl) propane, bis (3,5-dimethyl-4-maleimidophenyl) methane, bis(3-ethyl)-5-methyl-4-maleimidophenyl) methane, bis(3,5-diethyl-4-maleimidophenyl) methane, polyphenylmethanebismaleimide, maleimide having other biphenyl structure, but embodiments of the inventive concept are not limited thereto.

In addition, the bismaleimide-based polymer may be obtained from a prepolymer including a maleimide radical, and the prepolymer may include any one of or a mixture of at least two of, for example, n-phenylmaleimideprepolymer, n-(2-methylphenyl) maleimideprepolymer, n-(4-methylphenyl) maleimideprepolymer, n-(2,6-methylphenyl) maleimideprepolymer, bis (4-maleimidophenyl) methaneprepolymer, 2,2-bis (4-(4-maleimidophenoxy)-phenyl) propaneprepolymer, bis(3,5-dimethyl-4-maleimidophenyl) methaneprepolymer, bis(3-ethyl-5-methyl-4-maleimidophenyl) methaneprepolymer, bis(3,5-diethyl-4-maleimidophenyl) methaneprepolymer, polyphenylmethanebismaleimideprepolymer, maleimideprepolymer having non-phenyl structure, a prepolymer including N-phenylmaleimide and amine-based compound, prepolymer including N-(4-methylphenyl) maleimide and amine-based compound, prepolymer including N-(2,6-dimethylphenyl) maleimide and amine-based compound, prepolymer including bis (4-maleimidophenyl) methane and amine-based compound, prepolymer including 2,2-bis (4-(4-maleimidophenoxy)-phenyl) propane and amine-based compound, a prepolymer including bis(3,5-dimethyl-4-maleimidophenyl) methane and amine-based compound, a prepolymer including bis(3-ethyl-5-methyl-4-maleimidophenyl) methane and amine-based compound, a prepolymer including bis(3-diethyl-5-methyl-4-maleimidophenyl) methane and amine-based compound, a prepolymer including maleimide including non-phenyl structure and amine-based compound, or a prepolymer including polyphenylmethanebismaleimide and amine-based compound, but embodiments of the inventive concept are not limited thereto.

In some embodiments, the content of the thermosetting polymer TSR may be about 20 parts by weight to about 60 parts by weight based on 100 parts by weight of the chip attach film 10. For example, the content of the thermosetting polymer TSR may be about 20 parts by weight to about 60 parts by weight, about 20 parts by weight to about 50 parts by weight, or about 30 parts by weight to about 50 parts by weight based on 100 parts by weight of the chip attach film 10.

In some embodiments, the binder polymer TPR may include a thermoplastic polymer. The thermoplastic polymer may include one or more materials, such as, for example, an acryl-based polymer and/or a phenoxy-based polymer.

The acryl-based polymer may include an acryl-based polymer obtained by using radical polymerization with an acryl-based monomer as a raw material.

In some embodiments, the acryl-based monomer may include, for example, one or more of methyl(meth)acrylate, ethyl(meth)acrylate, propyl(meth)acrylate, isopropyl(meth)acrylate, butyl(meth)acrylate, isobutyl(meth)acrylate, hexyl(meth)acrylate, 2-ethylhexyl(meth)acrylate, n-octyl(meth)acrylate, isooctyl(meth)acrylate, n-nonyl(meth)acrylate, isononyl(meth)acrylate, n-decyl(meth)acrylate, isodecyl(meth)acrylate, n-dodecyl(meth)acrylate, n-tridecyl(meth)acrylate, n-tetradecyl(meth)acrylate, 2-hydroxyethyl(meth)acrylate, 2-hydroxypropyl(meth)acrylate, 4-hydroxybutyl(meth)acrylate, 6-hydroxyhexyl(meth)acrylate, 8-hydroxyoctyl(meth)acrylate, 10-hydroxydesil(meth)acrylate, 12-hydroxylauryl(meth)acrylate, (4-hydroxymethylcyclohexyl)methylacrylate, n-methylol(meth)acrylamide, ethyleneglycoldi(meth)acrylate, diethyleneglycoldi(meth)acrylate, tetraethyleneglycoldi(meth)acrylate, neopentylglycoldi(meth)acrylate, 1,6-hexandioldi(meth)acrylate, trimethylolpropanantri(meth)acrylate, pentaerythritoltri(meth)acrylate, dipentaerythritolhexa(meth)acrylate, divinylbenzene, n, n′-methylenebis acrylamide, or the like, but embodiments of the inventive concept are not limited thereto.

The phenoxy-based polymer may include polymer obtained by polymerizing monomers, such as one or more of phenoxyethyl acrylate, phenoxydiethyleneglycol acrylate, phenoxy polyethyleneglycol acrylate, nonylphenoxy polyethyleneglycol acrylate, nonylphenoxy polypropyleneglycol acrylate, nonylphenoxyethyleneglycol acrylate, and 2-hydroxy-3-phenoxypropyl(meth)acrylate. In some embodiments, the phenoxy-based polymer may include poly(2,6-dilauoryl-1,4-phenylene)ether, poly(2,6-diphenyl-1,4-phenylene)ether, poly(2-methyl-6-phenyl-1,4-phenylene)ether, poly(2,6-dibenzyl-1,4-phenylene)ether, poly(2,6-dimethyl-1,4-phenylene)ether, poly(2,6-diethyl-1,4-phenylene)ether, poly(2-methyl-6-ethyl-1,4-phenylene)ether, poly(2,6-dipropyl-1,4-phenylene)ether, poly(2-ethyl-6-propyl-1,4-phenylene)ether, poly(2-methyl-1,4-phenylene)ether, poly(3-methyl-1,4-phenylene)ether, poly(2-methyl-6-allyl-1,4-phenylene)ether, poly(2,3,6-trimethyl-1,4-phenylene)ether, poly(2,3,5,6-tetramethyl-1,4-phenylene)ether, poly(2,5-dimethyl-1,4-phenylene)ether, or the like, but embodiments of the inventive concept are not limited thereto.

In some embodiments, the content of the binder polymer TPR may be about 10 parts by weight to about 40 parts by weight based on 100 parts by weight of the chip attach film 10. For example, the content of the thermosetting polymer TSR may be about 10 parts by weight to about 40 parts by weight, about 20 parts by weight to about 40 parts by weight, or about 30 parts by weight to about 40 parts by weight based on 100 parts by weight of the chip attach film 10.

The filler 13 may be dispersed in the adhesive layer 11. For example, the filler 13 may be dispersed throughout the entire region of the adhesive layer 11. In FIG. 2, the filler 13 may be illustrated as a collection of circles.

Even when the chip attach film 10 is pressed according to the stacking of semiconductor chips during a manufacturing process, the thickness 10H of the chip attach film 10 may not decrease excessively because of the filler 13 supporting the adhesive layer 11, and may be maintained at a certain level.

In addition, because the filler 13 is dispersed throughout the entire region of the chip attach film 10, even when the chip attach film 10 is pressed while the semiconductor chips are stacked during the manufacturing process of the semiconductor package, the thickness 10H of the chip attach film 10 may be kept relatively uniform throughout the entire region of the chip attach film 10 in which the filler 13 is dispersed. For example, even when the semiconductor chip is stacked and the chip attach film 10 is pressed during the manufacturing process of the semiconductor package, the total thickness uniformity throughout the entire region of the chip attach film 10 may be about 0.1 μm or less.

The filler 13 may have a spherical shape. In some embodiments, the filler 13 may include a monodisperse filler of a spherical shape. For example, the filler 13 may include a monodisperse filler of a spherical shape having an average particle diameter 13H of about 1 μm.

In some embodiments, the filler 13 may include an organic material. In the embodiment, the filler 13 may include an organic material having a glass transition temperature of about 120° C. or less. For example, the filler 13 may include an organic material having a glass transition temperature of about 80° C. to about 120° C.

In some embodiments, the filler 13 may include a thermoplastic polymer. The thermoplastic polymer may include, for example, one or more of polystyrene, polymethylmethacrylate, and/or polyurethane.

In some embodiments, the average particle diameter 13H may be about 0.8 times or more of the thickness 10H of the chip attach film 10, and less than about 1 times the thickness 10H of the chip attach film 10. For example, the average particle diameter 13H of the filler 13 may about 0.9 times the thickness 10H of the chip attach film 10. When the average particle diameter 13H of the filler 13 is excessively large, there may be a limit in thinning the chip attach film 10. Conversely, when the average particle diameter 13H of the filler 13 is excessively small, and the chip attach film 10 is pressed while the semiconductor chips are stacked during the manufacturing process of the semiconductor package, the filler 13 may not support the adhesive layer 11, and the thickness 10H of the chip attach film 10 may be excessively reduced.

In some embodiments, the content of the filler 13 may be about 0.01 parts by weight to about 2 parts by weight based on 100 parts by weight of the chip attach film 10. For example, the content of the filler 13 may be about 0.01 parts by weight to about 2 parts by weight, about 0.1 parts by weight to about 2 parts by weight, about 0.5 parts by weight to about 2 parts by weight, or about 1 parts by weight to about 2 parts by weight based on 100 parts by weight of the chip attach film 10. When the content of the filler 13 is excessively large, the content of the adhesive layer 11 may be relatively reduced, and thus the mechanical properties of the chip attach film 10 may be reduced, and a thermal expansion coefficient of the chip attach film 10 may be increased. In addition, when the content of the filler 13 exceeds about 2 parts by weight, it may be difficult to reach the thickness 10H of the chip attach film 10.

In some embodiments, the chip attach film 10 may further include a cross-linking agent. The cross-linking agent may accelerate the curing of the adhesive layer 11, or change the curing reaction temperature of the adhesive layer 11 to a room temperature.

The cross-linking agent may include an anhydride-based cross-linking agent, such as one or more of tetrahydrophthalicanhydride, methyltetrahydrophthalicanhydride, methylhexahydrophthalicanhydride, hexahydrophthalicanhydride, thrylalkyltetrahydrophthalicanhydride, phthalicanhydride, maleic acidanhydride, and pyromelitic acidanhydride; an aromatic amine cross-linking agent, such as methphenylenediamine, diamininophenylmethane, and diaminophenylsulfone; an aliphatic amine cross-linking agent, such as diethylenetriamine and triethylenetetraamine; a phenolic cross-linking agent, such as phenolaralkyl-type phenol resin, phonolnovolac-type phenol resin, xylok-type phenol resin, cresolnovolac-type phenol resin, naphtol-type phenol resin, terpene-type phenol resin, polyfunctional phenol resin, dicyclopentadiene phenol resin, naphthalene-type phenol resin, and novolac-type phenolic resin synthesized from bisphenol A and resol; a latent cross-linking agent such as dicyandiamide; or the like, but embodiments of the inventive concept are not limited thereto. These cross-linking agents may be used alone or in a mixture of two or more.

In some embodiments, the chip attach film 10 may further include a curing speed regulator.

The curing speed regulator may include, for example, one or more of 1-methylimidazole, 2-methylimidazole, dimethylbenzylimidazole, 1-decyl-2-methylimidazole, benzyldimethylamine, trimethylamine, triethylamine, diethylaminopropylamine, pyridine, 1,8-diazabicyclo[5.4.0]undec-7-ene, 2-heptadecylimidazol, borontrifluoride monoethylamine, 1-[3(2-hydroxyphenyl) prop-2-enyl]imidazol, etc. However, embodiments of the inventive concept are not limited thereto.

The chip attach film 10 according to embodiments of the inventive concept may include the adhesive layer 11 and the filler 13 dispersed in the adhesive layer 11, and the average particle diameter 13H of the filler 13 may be about 0.8 times or more of the thickness 10H of the chip attach film 10 and less than about 1 times the thickness 10H of the chip attach film 10. Accordingly, when the semiconductor package is manufactured, even when the chip attach film 10 is pressed while the semiconductor chips are stacked, the filler 13 may support the adhesive layer 11, and the thickness 10H of the chip attach film 10 may not be excessively reduced but maintained at a generally constant level. In addition, because the filler 13 is dispersed throughout the entire region of the chip attach film 10, the thickness 10H of the chip attach film 10 may be maintained relatively uniform throughout the entire region of the chip attach film 10. In addition, because the chip attach film 10 includes a relatively small content of a filler (for example, about 0.01 parts by weight to about 2 parts by weight for 100 parts by weight of the chip attach film 10, the chip attach film 10 may be formed to have a relatively a small thickness.

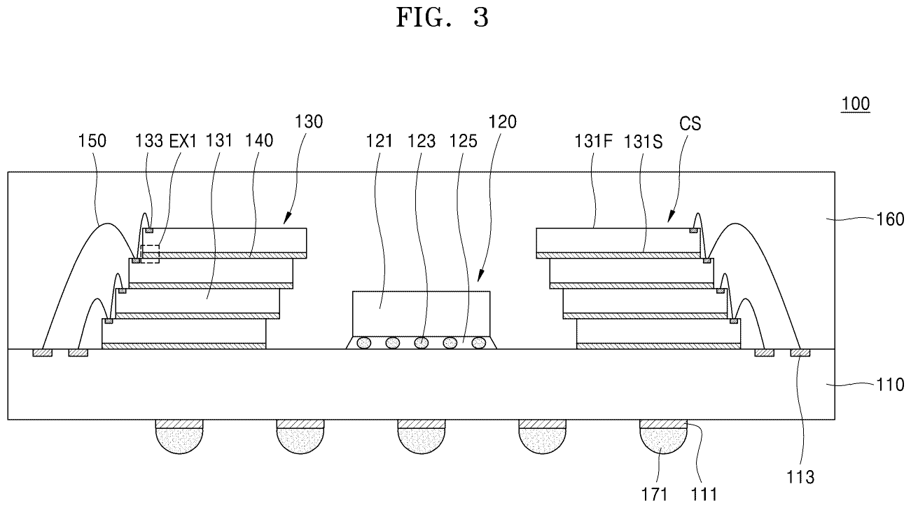

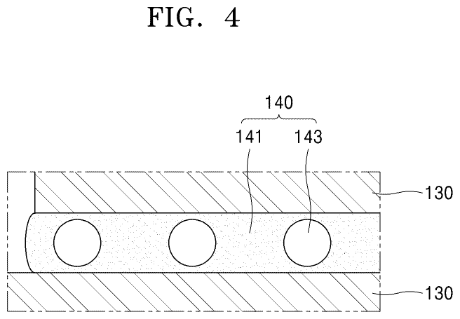

FIG. 3 is a cross-sectional view of a semiconductor package 100 according to an embodiment. FIG. 4 is an enlarged view of region EX1 in FIG. 3.

Referring to FIGS. 3 and 4, the semiconductor package 100 may include a substrate 110, a first semiconductor chip 120, a chip stack CS, and a molding layer 160.

The substrate 110 may include a printed circuit board (PCB), a flexible substrate, a tape substrate, etc.

The substrate 110 may include one or more materials, such as phenol resin, epoxy resin, and/or polyimide. For example, the substrate 110 may include frame retardant 4 (FR4), tetrafunctional epoxy, polyphenylene ether, epoxy/polyphenylene oxide, bismaleimide triazine (BT), thermount, cyanate ester, polyimide, and/or a liquid crystal polymer.

The substrate 110 may include a plurality of lower pads 111 and a plurality of upper pads 113. The plurality of lower pads 111 may be provided on a lower surface of the substrate 110, and the plurality of upper pads 113 may be provided on an upper surface of the substrate 110 as shown in the cross-sectional view of FIG. 3. The plurality of lower pads 111 and the plurality of upper pads 113 may be electrically connected to each other via a conductive pattern (not illustrated) provided inside the substrate 110. Each of the plurality of lower pads 111, the plurality of upper pads 113, and the conductive pattern may include a metal, such as aluminum, copper, tungsten, and/or titanium.

A plurality of external connection terminals 171 may be arranged on a lower surface of each of the plurality of lower pads 111. The plurality of external connection terminals 171 may be respectively connected to the plurality of lower pads 111. The external connection terminal 171 may include, for example, a solder ball. The external connection terminal 171 may include a solder material, for example, tin (Sn), silver (Ag), zinc (Zn), and/or a combination thereof.

The first semiconductor chip 120 may be arranged on an upper surface of the substrate 110. The first semiconductor chip 120 may be arranged in a relatively central portion region on the upper surface of the substrate 110.

The first semiconductor chip 120 may include a first semiconductor substrate 121. The first semiconductor substrate 121 may include a semiconductor material, such as silicon (Si) and/or germanium (Ge), and/or a compound semiconductor material, such as silicon carbide (SiC), gallium arsenide (GaAs), and/or indium phosphide (InP). The first semiconductor substrate 121 may include a conductive region, for example, a well doped with impurities. The first semiconductor substrate 121 may have various element isolation structures, such as a shallow trench isolation (STI) structure.

The first semiconductor substrate 121 may include a first active surface and a first inactive surface opposite to the first active surface. The first active surface may include various types of individual devices. The plurality of individual devices may include various microelectronic devices, for example, image sensors, such as a metal-oxide-semiconductor (MOS) field effect transistor (MOSFET) like a complementary MOS (CMOS), an image sensor, such as system large scale integration (LSI), and CMOS imaging sensors (CIS), and a logic device, such as micro-electro-mechanical system (MEMS), an active device, a passive device, a central processing unit (CPU), a micro processing unit (MPU), a graphics processing unit (GPU), an application processor (AP), a micro-controller, and/or an application-specific integrated circuit (ASIC).

A first connection terminal 123 may be arranged under the lower surface of the first semiconductor chip 120. The first connection terminal 123 may electrically connect the first semiconductor chip 120 to the substrate 110. The first connection terminal 123 may include, for example, a solder ball or a solder bump. The first connection terminal 123 may include a solder material, for example, tin (Sn), silver (Ag), zinc (Zn), and/or a combination thereof.

An under-fill layer 125 may be in and at least partially fill a region between the lower surface of the first semiconductor chip 120 and the upper surface of the substrate 110. The under-fill layer 125 may at least partially surround the first connection terminal 123 provided under the lower surface of the first semiconductor chip 120. The under-fill layer 125 may include, for example, an insulating material, but embodiments are not limited thereto.

The chip stack CS may be arranged over the upper surface of the substrate 110. The chip stack CS may be spaced apart horizontally from the first semiconductor chip 120 on the substrate 110. For example, the chip stack CS may be arranged, on the substrate 110, on the edge region of the substrate 110 to be spaced apart horizontally from the first semiconductor chip 120. The chip stack CS may include a plurality of second semiconductor chips 130 stacked in a vertical or second direction on the substrate 110. The plurality of second semiconductor chips 130 included in the chip stack CS may be stacked in the horizontal or first direction in a staircase structure or a cascade structure.

In some embodiments, unlike as illustrated in FIG. 3, the chip stack CS may also be arranged on the first semiconductor chip 120. In this case, the plurality of second semiconductor chips 130 of the chip stack CS may be stacked on the first semiconductor chip 120 in the vertical or second direction, and the second semiconductor chip 130 at the lowermost end among the plurality of second semiconductor chips 130 and the first semiconductor chip 120 may be bonded and fixed to each other by using a chip attach film 140 formed under an inactive surface 131S of the second semiconductor chip 130 located at the lowermost end.

The plurality of second semiconductor chips 130 may each include a second semiconductor substrate 131. The second semiconductor substrate 131 may have substantially the same material as the first semiconductor substrate 121 of the first semiconductor chip 120. The second semiconductor substrate 131 may include a conductive region, for example, a well doped with impurities. The second semiconductor substrate 131 may have various device isolation structures, such as a shallow trench isolation (STI) structure.

The second semiconductor substrate 131 may include a second active surface 131F and the inactive surface 131S opposite to the second active surface 131F. Various types of individual devices may be formed on the second active surface 131F of the second semiconductor substrate 131.

A chip pad 133 may be provided on the second active surface 131F of the second semiconductor substrate 131. The chip pad 133 may be arranged adjacent to one side surface relatively far from the first semiconductor chip 120 between both side surfaces of the second semiconductor substrate 131 in a plan view. The chip pad 133 may include a metal, for example, aluminum, copper, and/or titanium.

The chip attach film 140 may be provided on the inactive surface 131S of each of the plurality of second semiconductor chips 130. The chip attach film 140 may bond and fix the chip stack CS to the substrate 110, and the plurality of second semiconductor chips 130 to each other. Because the plurality of second semiconductor chips 130 are stacked in a staircase structure or a cascade structure in the horizontal or first direction, the chip attach film 140 may not cover or overlap the chip pad 133 of each of the plurality of second semiconductor chips 130 in the vertical or second direction.

The chip attach film 140 may extend from the side surface of each of the plurality of second semiconductor chips 130 in a side direction and protrude.

The chip attach film 140 may include an adhesive layer 141 and a filler 143. The adhesive layer 141 and the filler 143 of the chip attach film 140 may be substantially the same as the adhesive layer 11 and the filler 13 of the chip attach film 10 described with reference to FIGS. 1 and 2, respectively.

The first semiconductor chip 120 and the second semiconductor chip 130 may include memory chips or logic chips. For example, the first semiconductor chip 120 may include a logic chip, and the second semiconductor chip 130 may include a memory chip. The memory chip may include, for example, a volatile memory semiconductor chip, such as dynamic random access memory (RAM) (DRAM) and static RAM (SRAM), or a non-volatile memory chip, such as phase-change RAM (PRAM), magneto-resistive RAM (MRAM), ferroelectric RAM (FeRAM), and/or resistive RAM (RRAM). In addition, the logic chip may include, for example, a microprocessor, an analog element, a digital signal processor, etc.

In some embodiments, the first semiconductor chip 120 and the second semiconductor chip 130 may include semiconductor chips of the same type. For example, the first semiconductor chip 120 and the second semiconductor chip 130 may include memory chips.

In some embodiments, the first semiconductor chip 120 and the second semiconductor chip 130 may include semiconductor chips of different types. For example, the first semiconductor chip 120 may include a logic chip, and the second semiconductor chip 130 may include a memory chip.

A bonding wire 150 may be provided on the chip pad 133 of each of the plurality of second semiconductor chips 130. The bonding wire 150 may connect the chip pad 133 of the second semiconductor chip 130 to an upper pad 113 of the substrate 110, or may connect the chip pads 133 of each of the plurality of second semiconductor chips 130 to each other. Accordingly, the plurality of second semiconductor chips 130 may be electrically connected to the substrate 110 via the bonding wire 150, or each of the plurality of second semiconductor chips 130 may be electrically connected to each other via the bonding wire 150. The bonding wire 150 may include a metal, for example, gold (Au) or a gold alloy.

The molding layer 160 may be arranged on the substrate 110. The molding layer 160 may at least partially cover the first semiconductor chip 120, the plurality of second semiconductor chips 130, and the bonding wire 150. The molding layer 160 may include, for example, epoxy molding compound (EMC) material.

The semiconductor package 100 according to the embodiment may include the chip stack CS including the plurality of second semiconductor chips 130 and the chip attach film 140 including the adhesive layer 141 and the fillers 143 dispersed in the adhesive layer 141 between each of the plurality of second semiconductor chips 130. In this case, an average particle diameter of the filler 143 may be about 0.8 times or more of a thickness of the chip attach film 140, and less than about 1 times the thickness of the chip attach film 140. Accordingly, when the semiconductor package 100 is manufactured, even when the chip attach film 140 is pressed as the second semiconductor chips 130 are stacked, the filler 143 may support the adhesive layer 141 so that the thickness of the chip attach film 140 may not be excessively reduced but may be maintained at a generally constant level, and the thickness of the chip attach film 140 may be maintained relatively uniform over the entire area of the chip attach film 140 in which the fillers 143 are dispersed. Accordingly, the plurality of second semiconductor chips 130 may not be inclined and stacked, and thus, structural reliability of the semiconductor package 100 may be improved. In addition, because the chip attach film 140 includes a relatively small content amount of the filler 143 (for example, about 0.01 parts by weight to about 2 parts by weight for 100 parts by weight of the chip attach film 140, the chip attach film 140 may have a relatively a small thickness. Accordingly, the size of the semiconductor package 100 for bonding and fixing the plurality of second semiconductor chips 130 by using the chip attach film 140 may be reduced.

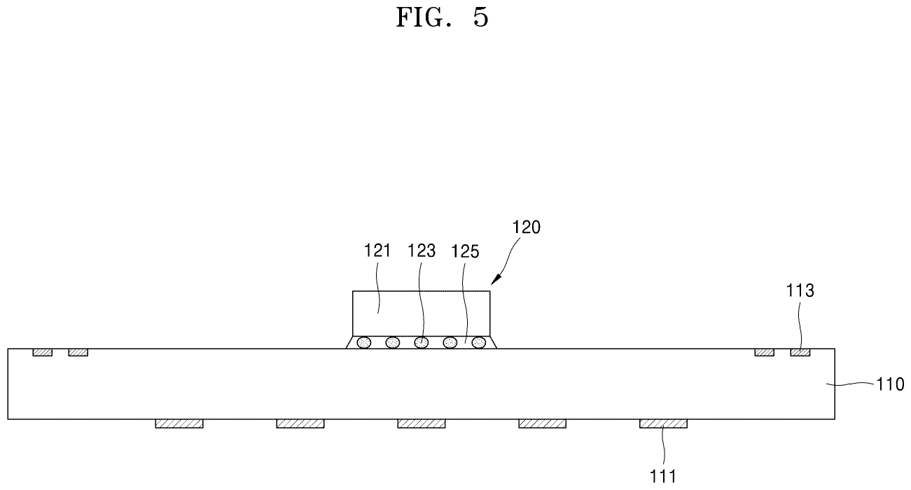

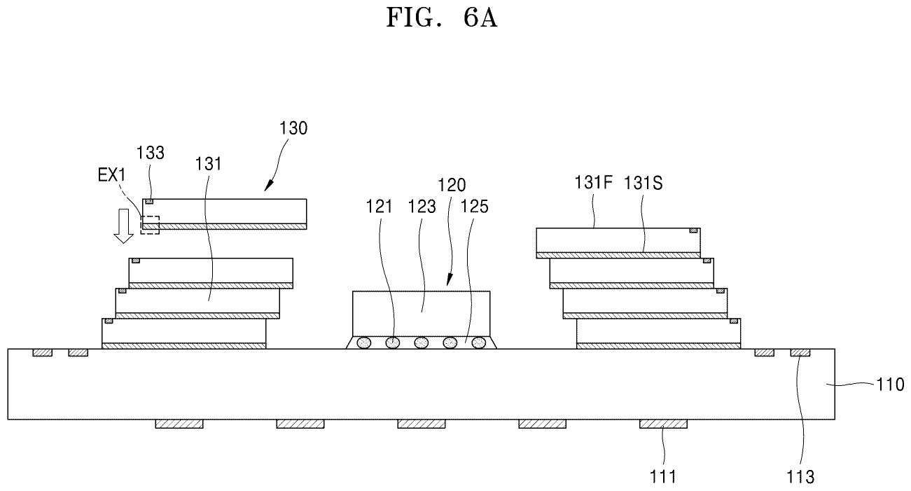

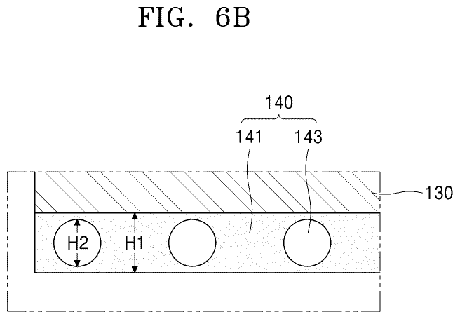

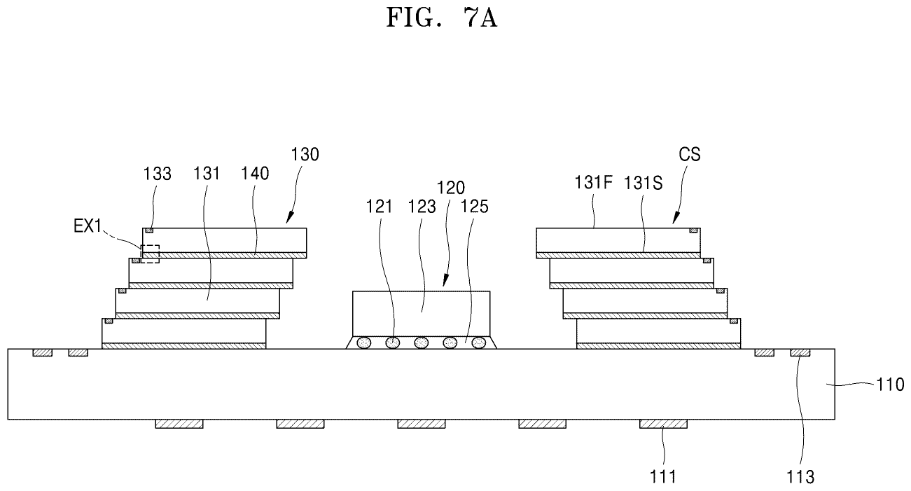

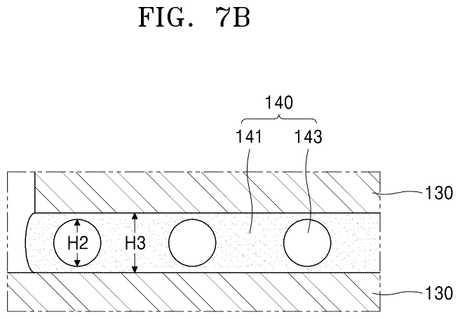

FIGS. 5, 6A, 7A, 8, and 9 are cross-sectional views illustrating a method of manufacturing the semiconductor package 100, according to embodiments. FIGS. 5, 6A, 7A, 8, and 9 are cross-sectional views of each operation of the method of manufacturing the semiconductor package 100, and FIGS. 6B and 7B are enlarged cross-sectional views of region EX1 in FIGS. 6A and 7A, respectively.

Referring to FIG. 5, first, the first semiconductor chip 120 may be mounted on the substrate 110. Specifically, the first semiconductor chip 120 including the first connection terminal 123 formed on the lower surface thereof may be mounted on the center portion region of the substrate 110. Next, the under-fill layer 125 may be in and at least partially fill a space between the lower surface of the first semiconductor chip 120 and the upper surface of the substrate 110.

Next, referring to FIGS. 6A, 6B, 7A, and 7B, by stacking the plurality of second semiconductor chips 130 on the substrate 110 in the vertical or second direction, the chip stack CS may be formed to be spaced apart horizontally from the first semiconductor chip 120.

First, the chip attach film 140 may be formed on one surface of a wafer including the plurality of second semiconductor chips 130. The one surface of the wafer may include a ground surface, and may correspond to the inactive surface 131S of each of the plurality of second semiconductor chips 130. The chip attach film 140 may be formed by forming an attach composition by mixing the thermosetting polymer (refer to TSR in FIG. 2), the binder polymer (refer to TPR in FIG. 2), the filler 143, or the like, and laminating the attach composition on one surface of the wafer. Next, by singulating the wafer including the chip attach film 140 formed on the one surface thereon, the plurality of second semiconductor chips 130 including the chip attach film 140 formed on the inactive surface 131S thereof may be provided.

The chip attach film 140 formed on the inactive surface 131S of the second semiconductor chip 130 may have a first thickness H1 in the vertical or second direction as illustrated in FIG. 6B, may not extend from the side surface of the second semiconductor chip 130 in the side direction, and may have the same horizontal area as the second semiconductor chip 130.

Next, the chip stack CS may be formed by stacking in the vertical or second direction each of the plurality of second semiconductor chips 130 including the chip attach film 140 formed on the inactive surface 131S of each of the plurality of second semiconductor chips 130.

First, one second semiconductor chip 130 may be arranged on the periphery region of the substrate 110 spaced apart horizontally from the first semiconductor chip 120. Next, by performing a thermo-compression process, the second semiconductor chip 130 and the substrate 110 may be bonded and fixed to each other by using the chip attach film 140.

Next, another second semiconductor chip 130 may be arranged on one second semiconductor chip 130, which has been arranged on the periphery region of the substrate 110. In this case, the another second semiconductor chip 130 may be arranged on the one second semiconductor chip 130 so that the another second semiconductor chip 130 forms a staircase structure of a cascade structure in a horizontal or first direction with the one second semiconductor chip 130. Next, by performing the thermo-compression process, the one second semiconductor chip 130 may be bonded and fixed to the another second semiconductor chip 130 by using the chip attach film 140.

Thereafter, by repeatedly performing the stacking process described above, the chip stack CS including the plurality of second semiconductor chips 130 may be formed.

In the embodiment, the thermo-compression process may be performed at a temperature higher than or equal to a glass transition temperature of the filler 143 included in the chip attach film 140. For example, a glass transition temperature of an organic material included in the filler 143 may be about 120° C., and the thermo-compression process may be performed at a temperature of about 120° C. or more.

On the other hand, in a stacking process of the plurality of second semiconductor chips 130, the chip attach film 140 may be pressed by performing a thermo-compression process thereon. Accordingly, as illustrated in FIG. 7B, the chip attach film 140 in the chip stack CS may extend from the side surface of the second semiconductor chip 130 and protrude therefrom.

In addition, the chip attach film 140 may have a second thickness H3 less than the first thickness H1 illustrated in FIG. 6B, by applying a compression process thereon. For example, the second thickness H3 illustrated in FIG. 7B may have a value less than the first thickness H1 illustrated in FIG. 6B by about 10% to about 20%. For example, the second thickness H3 illustrated in FIG. 7B may be about 0.5 μm to about 3 μm. In this case, the second thickness H3 may be greater than an average particle diameter H2, or may be substantially the same as the average particle diameter H2 of the filler 143. The reason may be because, even when the chip attach film 140 is pressed due to the thermo-compression process, the filler 143 supports the adhesive layer 141 and the second thickness H3 of the chip attach film 140 is maintained to be equal to or greater than the average particle diameter H2. Accordingly, the second thickness H3 of the chip attach film 140 may not be excessively reduced even after the thermo-compression process is completed, and may be maintained at a generally constant level.

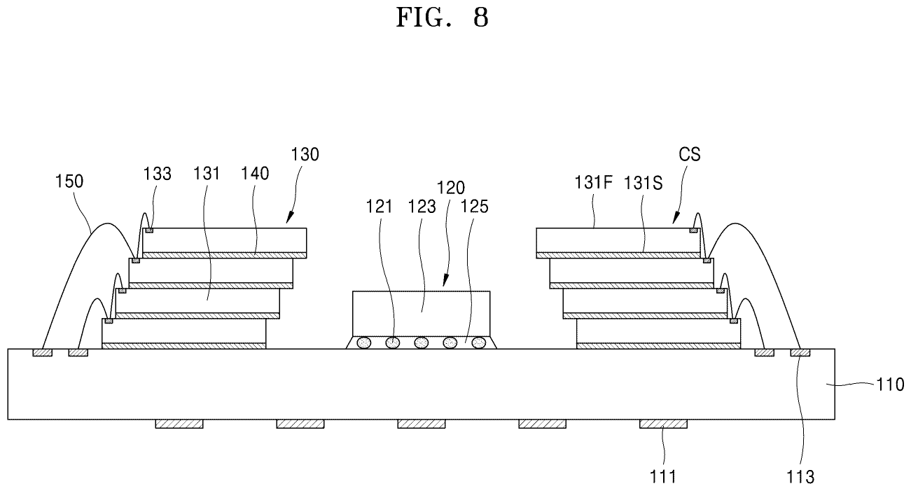

Next, referring to FIG. 8, the bonding wire 150 may be formed on the chip pad 133 of the plurality of second semiconductor chips 130 and the upper pad 113 of the substrate 110. The bonding wire 150 may be formed by using, for example, thermo-compression or an ultrasonic wave, but embodiments are not limited thereto.

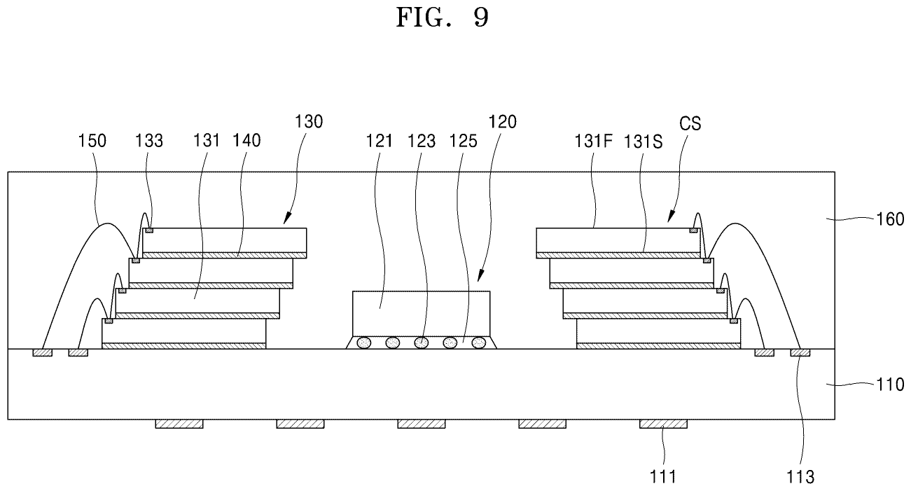

Next, referring to FIG. 9, the molding layer 160 on and at least partially covering the first semiconductor chip 120, the plurality of second semiconductor chips 130, and the bonding wire 150 may be formed.

Next, by forming the external connection terminal 171 on a lower pad 111 on the lower surface of the substrate 110 from the resultant product of FIG. 9, the semiconductor package 100 illustrated in FIG. 3 may be manufactured.

While the inventive concept has been particularly shown and described with reference to embodiments thereof, it will be understood that various changes in form and details may be made therein without departing from the spirit and scope of the following claims.

1. A chip attach film comprising:
an adhesive layer; and
a filler dispersed in the adhesive layer and including an organic material,
wherein a thickness of the adhesive layer is about 0.5 μm to about 3 μm, and
wherein an average particle diameter of the filler is equal to or greater than about 0.8 times the thickness of the adhesive layer, and less than about 1 times the thickness of the adhesive layer.

2. The chip attach film of claim 1, wherein a content of the filler is about 0.01 parts by weight to about 2 parts by weight based on 100 parts by weight of the chip attach film.

3. The chip attach film of claim 1, wherein the filler comprises a monodisperse filler of a spherical shape.

4. The chip attach film of claim 1, wherein the filler comprises a thermoplastic polymer.

5. The chip attach film of claim 4, wherein the thermoplastic polymer comprises polystyrene, polyurethane, or polymethylmethacrylate.

6. The chip attach film of claim 1, wherein the adhesive layer comprises a binder polymer and a thermosetting polymer.

7. The chip attach film of claim 6, wherein a content of the binder polymer is about 10 parts by weight to about 40 parts by weight based on 100 parts by weight of the chip attach film.

8. The chip attach film of claim 6, wherein a content of the thermosetting polymer is about 20 parts by weight to about 60 parts by weight based on 100 parts by weight of the chip attach film.

9. A semiconductor package comprising:
a substrate;
a first semiconductor chip on the substrate;
a chip stack which is on the substrate and includes a plurality of second semiconductor chips stacked in a second direction, and is spaced apart from the first semiconductor chip in a first direction; and
a bonding wire connected to the chip stack and the substrate,
wherein the chip stack further comprises a chip attach film between the stacked plurality of second semiconductor chips, and
wherein the chip attach film comprises: an adhesive layer; and a filler dispersed in the adhesive layer and comprising an organic material, a thickness of the chip attach film is about 0.5 μm to about 3 μm, and an average particle diameter of the filler is equal to or greater than about 0.8 times the thickness of the chip attach film and less than about 1 times the thickness of the chip attach film.

10. The semiconductor package of claim 9, wherein a content of the filler is about 0.01 parts by weight to about 2 parts by weight based on 100 parts by weight of the chip attach film.

11. The semiconductor package of claim 9, wherein the filler comprises a monodisperse filler having a spherical shape.

12. The semiconductor package of claim 9, wherein the filler comprises a thermoplastic polymer, and the thermoplastic polymer comprises polystyrene, polyurethane, or polymethylmethacrylate.

13. The semiconductor package of claim 9, wherein the filler comprises an organic material having a glass transition temperature of about 120° C. or less.

14. The semiconductor package of claim 9,
wherein the adhesive layer comprises binder polymer and thermosetting polymer, a content of the binder polymer is about 10 parts by weight to about 40 parts by weight based on 100 parts by weight of the chip attach film, and a content of the thermosetting polymer is about 20 parts by weight to about 60 parts by weight based on 100 parts by weight of the chip attach film.

15. The semiconductor package of claim 14,
wherein the binder polymer comprises a thermoplastic polymer, and the thermoplastic polymer comprises acryl-based polymer or phenoxy-based polymer.

16. The semiconductor package of claim 14, wherein the thermosetting polymer comprises an epoxy-based polymer.

17. A method of manufacturing a semiconductor package, the method comprising:
mounting a first semiconductor chip on a substrate;
forming a chip stack spaced apart in a first direction from the first semiconductor chip on the substrate;
forming a bonding wire connected to the chip stack and the substrate; and
forming a molding layer on the first semiconductor chip, the chip stack, and the bonding wire,
wherein the forming of the chip stack comprises stacking a plurality of second semiconductor chips in a second direction including a chip attach film formed on one surface of the plurality of second semiconductor chips, and
wherein the chip attach film comprises: an adhesive layer; and a filler dispersed in the adhesive layer and comprising an organic material, a thickness of the chip attach film is about 0.5 μm to about 3 μm, and an average particle diameter of the filler is equal to or greater than about 0.8 times the thickness of the chip attach film and less than about 1 times the thickness of the chip attach film.

18. The method of claim 17,
wherein the stacking of the plurality of second semiconductor chips in the second direction comprises performing a thermo-compression process, and the thermo-compression process is performed at a temperature equal to or greater than a glass transition temperature of the filler.

19. The method of claim 17, wherein a content of the filler is about 0.01 parts by weight to about 2 parts by weight based on 100 parts by weight of the chip attach film.

20. The method of claim 17, wherein the filler comprises a monodisperse filler having a spherical shape.

21-24. (canceled)
